(19) United States
(12) Patent Application Publication
(10) Pub. No.: US 2014/0293683 A1
(43) Pub. Date: Oct. 2, 2014

(54) MAGNETO-RESISTIVE EFFECT ELEMENT

(71) Applicants: TOKYO INSTITUTE OF TECHNOLOGY, (US); THE REGENTS OF THE UNIVERSITY OF CALIFORNIA, (US)

(72) Inventors: Yutaka MAJIMA, Tokyo (JP); Shinya KANO, Tokyo (JP); Hideo HOSONO, Tokyo (JP); Hideya KUMOMI, Tokyo (JP); Ali JAVEY, Lafayette, CA (US); Kuniharu TAKEI, Osaka (JP)

(21) Appl. No.: 13/854,336

(22) Filed: Apr. 1, 2013

(51) Int. Cl. H01L 43/08; G11C 11/16; H01L 43/12; H03K 19/18

(52) U.S. Cl. CPC H01L 43/08; H03K 19/18; G11C 11/165; H01L 43/12
USPC 365/158; 257/421; 326/38; 438/3

(57) ABSTRACT

[PURPOSE]

According to the invention there is provided a magneto-resistive effect element having a larger magneto-resistive ratio than in the prior art.

[SOLUTION MEANS]

The magneto-resistive effect element (10) of the invention has a compound semiconductor layer (11) composed of a compound semiconductor such as InAs, metal layers (12A and 12B) composed of a metal element such as Ni not composing the compound semiconductor, and interlayers (13A and 13B) of NiInAs or the like composed of the constituent elements of the compound semiconductor and a metal element, situated between the compound semiconductor layer and the metal layer. In the magneto-resistive effect element (10) of the invention, application of a magnetic field (50) alters the conductance with respect to the electric current (60) flowing through the metal layer (12B), interlayer (13B), compound semiconductor layer (11), interlayer (13A) and metal layer (12A).

### TECHNICAL FIELD

The present invention relates to a magneto-resistive effect element.

### BACKGROUND ART

Magneto-resistive effect elements employing giant magneto-resistive (GMR) and tunneling magneto-resistive (TMR) effects are widely used in the prior art, in the read heads of hard disk drive devices, and in magnetic memory devices, and research and development is advancing toward higher performance.

The magneto-resistive ratio is an important characteristic of a magneto-resistive effect element. The magneto-resistive ratio is the ratio of electrical resistance values for a magneto-resistive effect element, between the ON state and the OFF state of the element. In currently employed magneto-resistive effect elements, the magneto-resistive ratio is no more than a few hundred percent (a few folds) (Non Patent Document 1). Improving the magneto-resistive ratio is important for achieving high performance of read heads in hard disk drive devices, and magnetic memory devices, and it is therefore a crucial issue in the field of electronics at the current time.

In Non Patent Document 2, the present inventors have reported that heat treatment of a field-effect transistor having a Ni layer vapor deposited on an InAs nanowire results in diffusion of the Ni in the InAs layer and formation of a NiInAs layer. This causes Ohmic contact between the Ni and InAs nanowire, and can lower contact resistance. Also, in Non Patent Documents 3 and 4, an InAs layer formed on GaSb by molecular beam epitaxy is placed on a silicon oxide film, a Ni layer is vapor deposited thereover to obtain an InAs layer and Ni layer stack, and the obtained stack is subjected to annealing treatment (heat treatment) to form a NiInAs layer between the InAs layer and the Ni layer, the element obtained in this manner functioning as a field-effect transistor.

### NON-PATENT LITERATURE

[Non Patent Document 1] S. Ikeda, J. Hayakawa, Y. M. Lee, F. Matsukura, Y. Ohno, T. Hanyu, H. Ohno, IEEE Trans. Electron Devices 54 991 (2007).
[Non Patent Document 2] Y.-L. Chueh, A. C. Ford, J. C. Ho, Z. A. Jacobson, Z. Fan, C.-Y. Chen, L.-J. Chou, A. Javey, Nano Lett. 8 4528-4533 (2008).
[Non Patent Document 3] H. Ko, K. Takei, R. Kapadia, S. Chuang, H. Fang, P. W. Leu, K. Ganapathi, E. Plis, H. S. Kim, S.-Y. Chen, M. Madsen, A. C. Ford, Y.-L. Chueh, S. Krishna, S. Salahuddin, A. Javey, Nature 468 286-289 (2010).
[Non Patent Document 4] K. Takei, H. Fang, S. B. Kumar, R. Kapadia, Q. Gao, M. Madsen, H. S. Kim, C.-H. Liu, Y.-L. Chueh, E. Plis, S. Krishna, H. A. Bechtel, J. Guo, and A. Javey, Nano Lett. 11 5008-5012 (2011).

### DISCLOSURE OF THE INVENTION

### Problems to be Solved by the Invention

Improving the magneto-resistive ratio is currently an important topic in the field of electronics. In light of this issue, the present invention provides a magneto-resistive effect element having a larger magneto-resistive ratio than in the prior art.

### Means for Solving the Problems

As a result of diligent research, the present inventors have devised the following invention.

(1) A magneto-resistive effect element, comprising:

a compound semiconductor layer composed of a compound semiconductor,

a metal layer composed of a metal element not composing the compound semiconductor, and

an interlayer between the compound semiconductor layer and the metal layer, composed of the constituent elements of the compound semiconductor and the metal element,

wherein application of a magnetic field alters the conductance with respect to electric current flowing from the compound semiconductor layer side through the interlayer to the metal layer side, and/or electric current flowing in the opposite direction.

(2) A magneto-resistive effect element according to (1) above, wherein the magnetic field is a magnetic field applied in the in-plane direction of the interlayer.

(3) A magneto-resistive effect element according to (1) or (2) above, wherein the conductance is altered by a factor of at least 10³ upon application of the magnetic field.

(4) A magneto-resistive effect element according to (3) above, wherein the conductance is altered by a factor of at least 10³ in a 50 mT magnetic field range, upon application of the magnetic field.

(5) A magneto-resistive effect element according to any one of (1) to (4) above,

wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, and

wherein the first threshold magnetic field is larger than the second threshold magnetic field.

(6) A magneto-resistive effect element according to (5) above, wherein the first threshold magnetic field is at least 30 mT larger than the second threshold magnetic field.

(7) A magneto-resistive effect element according to (5) or (6) above, wherein the second threshold magnetic field is a magnetic field in the same direction as the first threshold magnetic field, and the absolute value of the first threshold magnetic field is larger than the absolute value of the second threshold magnetic field.

(8) A magneto-resistive effect element according to any one of (1) to (7) above, wherein the compound semiconductor contains In.

(9) A magneto-resistive effect element according to (8) above, wherein the compound semiconductor contains As.

(10) A magneto-resistive effect element according to (8) above, wherein the compound semiconductor contains Sb.

(11) A magneto-resistive effect element according to any one of (1) to (10) above, wherein the metal element is Ni.

(12) A magneto-resistive memory having a magneto-resistive effect element of any one of (1) to (11) above.

(13) A method of driving a magneto-resistive memory of (12) above,

wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, the first threshold magnetic field being larger than the second threshold magnetic field, and

wherein the method of driving a magneto-resistive memory comprises the following steps:

(a) applying a magnetic field equal to or larger than the first threshold magnetic field to the interlayer to increase the conductance, thereby writing a state of increased conductance onto the magneto-resistive effect element,

(b) applying a magnetic field smaller than the second threshold magnetic field to the interlayer to decrease the conductance, thereby writing a state of decreased conductance onto the magneto-resistive effect element, and

(c) following the step (a) or (b), evaluating the conductance while applying to the interlayer a magnetic field that is smaller than the first threshold magnetic field and equal to or larger than the second threshold magnetic field, to judge whether the state is one of increased or decreased conductance.

(14) A magneto-resistive switch, having a magneto-resistive effect element of any one of (1) to (11) above.

(15) A method of driving a magneto-resistive switch of (14) above,

wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, the first threshold magnetic field being larger than the second threshold magnetic field, and

wherein the method of driving a magneto-resistive switch comprises the following steps:

(a) applying a magnetic field equal to or larger than the first threshold magnetic field to the interlayer to create a state of increased conductance, thereby producing an ON state for electric current flowing from the compound semiconductor layer side through the interlayer toward the metal layer side, and/or in the opposite direction, and

(b) applying a magnetic field smaller than the second threshold magnetic field to the interlayer to create a state of decreased conductance, thereby producing an OFF state for electric current flowing from the compound semiconductor layer side through the interlayer toward the metal layer side, and/or in the opposite direction.

(16) A method for producing a magneto-resistive effect element of any one of (1) to (11) above, the method comprising:

providing a stack of a compound semiconductor layer composed of a compound semiconductor and a metal layer composed of a metal element not composing the compound semiconductor, and

subjecting the stack to annealing treatment to form an interlayer between the compound semiconductor layer and the metal layer, composed of the constituent elements of the compound semiconductor and the metal element.

(17) The method according to (16) above, wherein the annealing treatment is conducted in a temperature range of between 150° C. and 600° C.

(18) A magneto-resistive effect element with conductance that varies depending on the magnetic field applied,

wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, and

wherein the first threshold magnetic field is larger than the second threshold magnetic field.

(19) A magneto-resistive effect element according to (18) above, wherein the first threshold magnetic field is at least 30 mT larger than the second threshold magnetic field.

(20) A magneto-resistive effect element according to (18) or (19) above, wherein the conductance is altered by a factor of at least 10³ upon application of the magnetic field.

(21) A magneto-resistive effect element according to any one of (18) to (20) above, wherein the second threshold magnetic field is a magnetic field in the same direction as the first threshold magnetic field, and the absolute value of the first threshold magnetic field is larger than the absolute value of the second threshold magnetic field.

(22) A method of driving a magneto-resistive memory having a magneto-resistive effect element of any one of (18) to (21) above, which comprises the following steps:

(a) applying a magnetic field equal to or larger than the first threshold magnetic field to the interlayer to increase the conductance, thereby writing a state of increased conductance onto the magneto-resistive effect element,

(b) applying a magnetic field smaller than the second threshold magnetic field to the interlayer to decrease the conductance, thereby writing a state of decreased conductance onto the magneto-resistive effect element, and

(c) following the step (a) or (b), evaluating the conductance while applying to the interlayer a magnetic field that is smaller than the first threshold magnetic field and equal to or larger than the second threshold magnetic field, to judge whether the state is one of increased or decreased conductance.

(23) A method of driving a magneto-resistive switch having a magneto-resistive effect element of any one of (18) to (21) above, comprising the following steps:

(a) applying a magnetic field equal to or larger than the first threshold magnetic field to the interlayer to create a state of increased conductance, thereby producing an ON state for electric current flowing from the compound semiconductor layer side through the interlayer toward the metal layer side, and/or in the opposite direction, and

(b) applying a magnetic field smaller than the second threshold magnetic field to the interlayer to create a state of decreased conductance, thereby producing an OFF state for electric current flowing from the compound semiconductor layer side through the interlayer toward the metal layer side and/or in the opposite direction.

### BRIEF DESCRIPTION OF THE DRAWINGS

FIG. 1 is a cross-sectional view schematically showing a first embodiment of the magneto-resistive element of the present invention.

FIG. 2 is a cross-sectional view schematically showing a second embodiment of the magneto-resistive element of the present invention.

FIG. 3 is a cross-sectional view schematically showing a third embodiment of the magneto-resistive element of the present invention.

FIG. 4 is a cross-sectional view schematically showing a fourth embodiment of the magneto-resistive element of the present invention.

FIG. 5 is a view schematically showing the relationship between electric field applied to the magneto-resistive element of the present invention, and conductance.

FIG. 6 is a view showing the magneto-resistive effect at 9K, for the magneto-resistive element of Example 1 having the structure shown in FIG. 1.

FIG. 7 is a view showing magnetic memory behavior at 9K, for the magneto-resistive element of Example 1 having the structure shown in FIG. 1.

FIG. 8 is a view showing the magneto-resistive effect at room temperature, for the magneto-resistive element of Example 1 having the structure shown in FIG. 1.

FIG. 9 is a view showing the magneto-resistive effect at 240K, for the magneto-resistive element of Example 2 having the structure shown in FIG. 2.

### EFFECT OF THE INVENTION

With the magneto-resistive effect element of the present invention, it is possible to provide unexpected properties such as significantly high conductance change, compared to conventional magneto-resistive effect elements. With the magneto-resistive memory of the invention, it is possible to efficiently record data by recording operations.

### EMBODIMENTS FOR CARRYING OUT THE INVENTION

Embodiments of the invention will now be explained in detail with reference to the accompanying drawings.

### <Magneto-Resistive Effect Element>

### First Embodiment

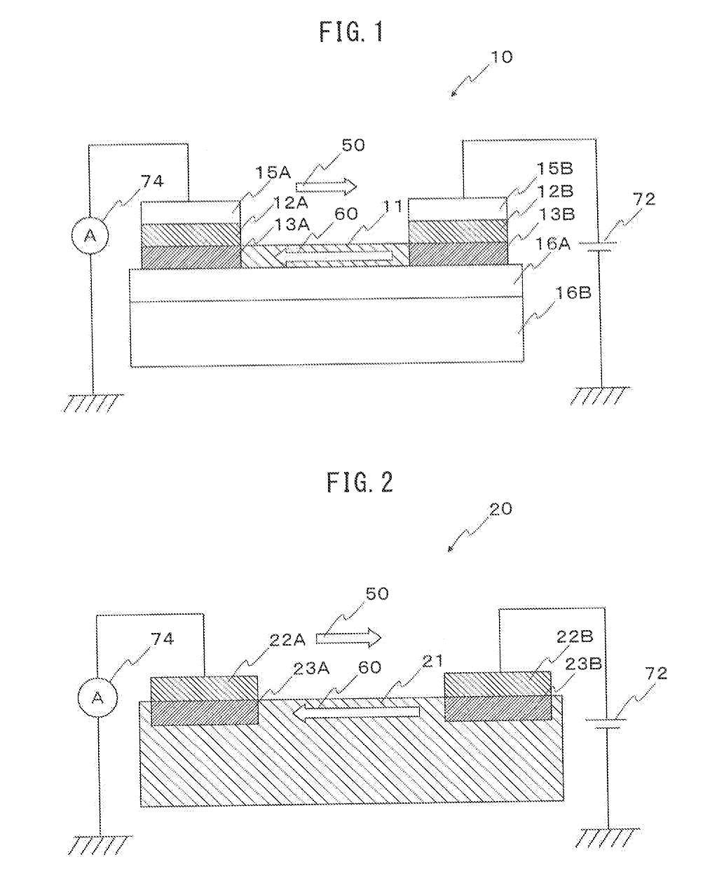

As shown in the cross-sectional view of an element in FIG. 1, the first embodiment (10) of the magneto-resistive effect element of the present invention has a compound semiconductor layer (11) composed of a compound semiconductor such as InAs, metal layers (12A and 12B) composed of a metal element such as Ni not composing the compound semiconductor, and interlayers (13A and 13B) such as NiInAs composed of the constituent elements of the compound semiconductor and a metal element, situated between the compound semiconductor layer and the metal layer.

According to this embodiment, the compound semiconductor layer (11) and interlayers (13A and 13B) are disposed on substrates (16A and 16B), for example, a conductive silicon substrate (16B) having an insulating coating (16A) such as a silicon oxide film.

The interlayers 13A and 13B are shown schematically bordering on the insulating coating 16A, but this is not necessarily limitative so long as the layers are electrically connected in series in the order: metal layers 12A and 12B, interlayers 13A and 13B, compound semiconductor layer 11. For example, instead of the interlayers 13A and 13B bordering the insulating coating 16A, the compound semiconductor layer 11 may be situated under the interlayers 13A and 13B, and the compound semiconductor layer 11 may be bordering with the insulating coating 16A.

Also, according to this embodiment, optional additional metal layers (15A and 15B), such as layers of a precious metal such as Au to inhibit oxidation of the metal layer such as Ni, are formed on the metal layer such as Ni.

In the magneto-resistive effect element (10) of the invention, application of a magnetic field (50), particularly a magnetic field applied in the in-plane direction of the interlayers (13A and 13B), alters the conductance with respect to the electric current (60) flowing through the metal layer (12B), interlayer (13B), compound semiconductor layer (11), interlayer (13A) and metal layer (12A). Specifically, the conductance can be evaluated, for example, by measuring the magnitude of the electric current flowing from a power source (72), using an ammeter (74).

This change in conductance with application of the magnetic field is very large and may be, for example, 10³-fold or more, 10⁴-fold or more, 10⁵-fold or more, 10⁶-fold or more, or even 10⁷-fold or more. This change in conductance with application of the magnetic field is also very precipitous and may be, for example, 10³-fold or more, 10⁴-fold or more, 10⁵-fold or more, 10⁶-fold or more, or even 10⁷-fold or more, in a magnetic field range of 50 mT, 40 mT, 30 mT, 20 mT or 10 mT.

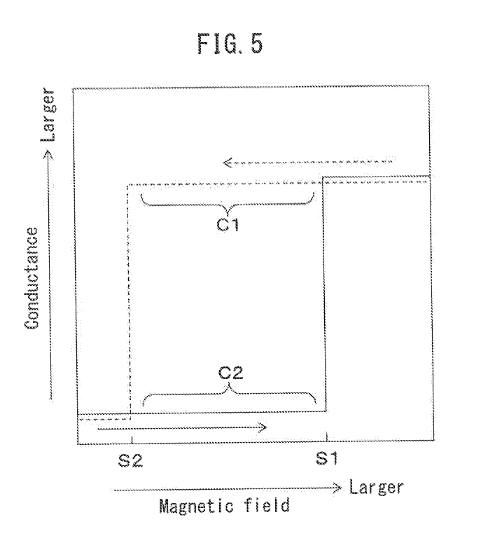

As shown in FIG. 5, the magneto-resistive effect element of the present invention has a first threshold magnetic field (S1) wherein the conductance increases as the strength of the magnetic field is increased, and a second threshold magnetic field (S2) wherein the conductance decreases as the strength of the magnetic field is decreased from a larger magnetic field than the first threshold magnetic field (S1).

The first threshold magnetic field (S1) is the value of the magnetic field determined in a range where the conductance increases as the strength of the magnetic field is increased, and the second threshold magnetic field (S2) is the value of the magnetic field determined in a range where the conductance decreases as the strength of the magnetic field is decreased from a larger magnetic field than the first threshold magnetic field.

Thus, the first and second threshold magnetic fields may be the values of the magnetic fields corresponding to the geometrical mean of the maximum (A) of increased conductance and the minimum (B) of decreased conductance ((A×B)^{1/2}). Also, the maximum (A) and minimum (B) may be the maximum and minimum within the range of magnetic field values applied to the magneto-resistive effect element during use of the magneto-resistive effect element.

In the magneto-resistive effect element of the present invention, the first threshold magnetic field (S1) is larger than the second threshold magnetic field (S2), and it may be at least 30 mT, at least 50 mT, at least 100 mT or at least 150 mT larger, for example.

Also, in the magneto-resistive effect element of the present invention, the second threshold magnetic field (S2) may be a magnetic field in the same direction as the first threshold magnetic field (S1), and the absolute value of the first threshold magnetic field may be larger than the absolute value of the second threshold magnetic field.

With a conventional magneto-resistive effect, starting from the state wherein magnetic field is applied, the magneto-resistive is low, and magnetization is alignment, when a magnetic field sweep from this state will partially invert the orientation of magnetization at the point where the magnetic field orientation becomes reversed (0 field is transversed), resulting in a high resistance state; and when the strength of the magnetic field is further increased, the overall orientation of magnetization aligns in the direction opposite that before sweeping the magnetic field, resulting in a low resistance state. In contrast, according to the present invention using a magneto-resistive effect element of the present invention, a high resistance state results before the state with no magnetic field.

In the magneto-resistive effect element of the present invention, the compound semiconductor may contain In, and it may further contain As and/or Sb. Consequently, the compound semiconductor may be composed of a combination of In and As, a combination of In and Sb or a combination of In, As and Sb. Also, the metal element in the magneto-resistive effect element of the present invention may be Ni.

According to the invention, the expression “composed of” for elements of the compound semiconductor refers to the essential elements for obtaining the compound semiconductor, and there may be included, in addition to the essential elements, non-essential elements such as impurities and additives, in trace amounts. In other words, the “compound semiconductor” of the invention may include elements other than those essential for obtaining the compound semiconductor, such as trace impurities that act as substitute dopants for determining the conductivity of the compound semiconductor, or unavoidable impurities introduced during production, that act as defects.

The magneto-resistive effect element of the present invention also has a pin layer, i.e. a layer in which the magnetic field direction is fixed such as a ferromagnetic layer adjacent to the antiferromagnetic layer. By providing a fixed bias magnetic field, it is possible to adjust the magnetic field applied to the interlayer when no magnetic field is being provided externally.

### First Embodiment

### Magneto-Resistive Memory

As mentioned above, for use of the magneto-resistive effect element of the present invention in a magneto-resistive memory, it is preferable that the first threshold magnetic field (S1) is larger than the second threshold magnetic field (S2), and optionally that the second threshold magnetic field (S2) is a magnetic field in the same direction as the first threshold magnetic field (S1), and the absolute value of the first threshold magnetic field is larger than the absolute value of the second threshold magnetic field.

Specifically, a method comprising the following steps can be used to drive a magneto-resistive memory provided with the magneto-resistive effect element:

(a) a magnetic field equal to or larger than the first threshold magnetic field (S1) is applied to the interlayer to increase the conductance, thereby writing a state of increased conductance (C1) in the magneto-resistive effect element,

(b) a magnetic field smaller than the second threshold magnetic field (S2) is applied to the interlayer to decrease the conductance, thereby writing a state of decreased conductance (C2) in the magneto-resistive effect element,

(c) following the step (a) or (b), with a magnetic field smaller than the first threshold magnetic field (S1) and equal to or larger than the second threshold magnetic field (S2) is applied to the interlayer, the conductance is evaluated to judge whether there is a state of increased conductance (C1) or a state of decreased conductance (C2).

Specifically, for example, using this method of driving wherein a state of increased conductance (C1) corresponds to “1” and a state of decreased conductance (C2) corresponds to “0”, the magneto-resistive effect element can be used as a memory element for a magneto-resistive memory.

In this regard, the magneto-resistive effect element of the present invention that further has a pin layer as explained above, can adjust the magnetic field applied to the interlayer when no external magnetic field is provided. Consequently, when no external magnetic field is being provided, a magnetic field that is smaller than the first threshold magnetic field (S1) and equal to or larger than the second threshold magnetic field (S2) can be applied to the interlayer by the pin layer, i.e. it can be judged whether the state is one of increased conductance (C1) or one of decreased conductance (C2).

### First Embodiment

### Magneto-Resistive Switch

As mentioned above, for use of the magneto-resistive effect element of the present invention in a magneto-resistive switch, i.e. a switch in which current is turned ON/OFF by application of a magnetic field, it is preferable that the first threshold magnetic field (S1) is larger than the second threshold magnetic field (S2), and optionally that the second threshold magnetic field (S2) is a magnetic field in the same direction as the first threshold magnetic field (S1), and the absolute value of the first threshold magnetic field is larger than the absolute value of the second threshold magnetic field. The magneto-resistive effect element of the present invention is also desirable for use in a magneto-resistive switch, because this change in conductance is extremely large upon application of a magnetic field.

Specifically, a method comprising the following steps can be used to drive a magneto-resistive switch having the magneto-resistive effect element:

(a) a magnetic field equal to or larger than the first threshold magnetic field (S1) is applied to the interlayer to create a state of increased conductance (C1), thereby producing an ON state for electric current flowing from the compound semiconductor layer side through the interlayer to the metal layer side, and/or in the opposite direction, and

(b) a magnetic field smaller than the second threshold magnetic field (S2) is applied to the interlayer to create a state of decreased conductance (C2), thereby producing an OFF state for electric current flowing from the compound semiconductor layer side through the interlayer to the metal layer side, and/or in the opposite direction.

In this regard, the magneto-resistive effect element of the present invention that further has a pin layer as explained above, can adjust the magnetic field applied to the interlayer when no external magnetic field is provided. In other words, a magnetic field that is equal to or larger than the first threshold magnetic field (S1) may be applied to the interlayer by the pin layer when no external magnetic field is being provided, for switching of the electric current to the ON state. Conversely, a magnetic field that is smaller than the second threshold magnetic field (S2) may be applied to the interlayer by the pin layer when no external magnetic field is being provided, for switching of the electric current to the OFF state.

### First Embodiment

### Production Method

The magneto-resistive effect element of the present invention can be produced by a method comprising the following steps, for example:

providing a stack of a compound semiconductor layer composed of a compound semiconductor, and a metal layer composed of a metal element that is not composing the compound semiconductor, and

subjecting the stack to annealing treatment, for example, heating at a temperature of 150° C. or higher, 200° C. or higher or 250° C. or higher, and no higher than 600° C., no higher than 500° C. or no higher than 400° C., for a period of, for example, 5 seconds or longer, 10 seconds or longer, 20 seconds or longer or 30 seconds or longer, and no longer than 10 minutes, no longer than 5 minutes or no longer than 3 minutes, to form an interlayer between the compound semiconductor layer and the metal layer, which is composed of the constituent elements of the compound semiconductor and the metal element.

The interlayer of the magneto-resistive effect element of the present invention is formed between the layers by annealing treatment of the stack of the compound semiconductor layer and the metal layer. In particular, the annealing treatment may be carried out under a nitrogen atmosphere, at a temperature of 300° C. for 1 minute.

### Second Embodiment

As shown in the cross-sectional view of an element in FIG. 2, the second embodiment of the magneto-resistive effect element of the present invention has a compound semiconductor layer (21) composed of a compound semiconductor such as InAs, metal layers (22A and 22B) composed of a metal element such as Ni not composing the compound semiconductor, and interlayers (23A and 23B) of NiInAs or the like composed of the constituent elements of the compound semiconductor and a metal element, the interlayers being situated between the compound semiconductor layer and the metal layer.

According to this embodiment, the compound semiconductor layer (21) forms the substrate, the metal layers (22A and 22B) are formed on the substrate, and portions of the substrate constitute the interlayers (23A and 23B).

While not shown here, another metal layer, for example, a layer of a precious metal such as Au to inhibit oxidation of the metal layer such as Ni, may be formed on the metal layer such as Ni for this embodiment, similar to the first embodiment.

In the magneto-resistive effect element (20) of the invention, application of a magnetic field (50), particularly a magnetic field applied in the in-plane direction of the interlayers (23A and 23B), alters the conductance with respect to the electric current (60) flowing through the metal layer (22B), interlayer (23B), compound semiconductor layer (21), interlayer (23A) and metal layer (22A). Specifically, the conductance can be evaluated, for example, by measuring the magnitude of the electric current flowing from a power source (72), using an ammeter (74).

The description of the first embodiment of the magneto-resistive effect element of the present invention applies with regard to the other aspects.

### Third Embodiment

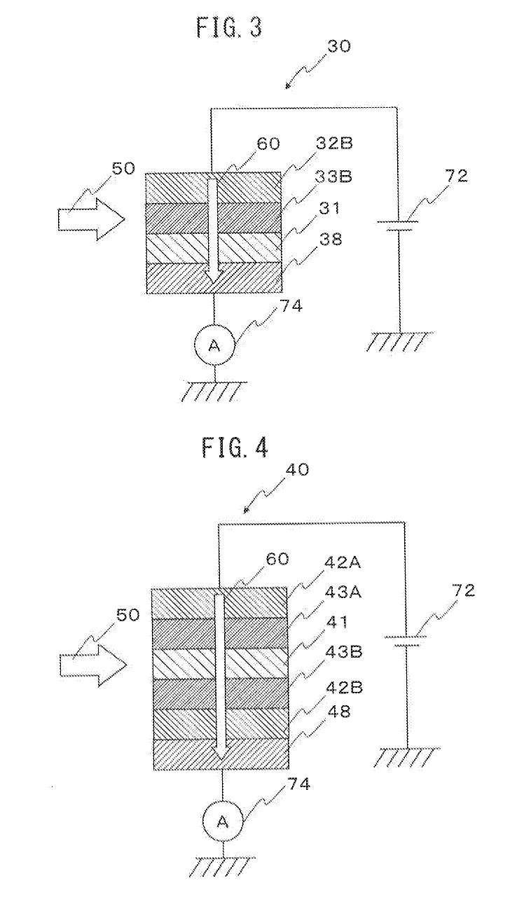

As shown in the cross-sectional view of an element in FIG. 3, the third embodiment of the magneto-resistive effect element of the present invention has a compound semiconductor layer (31) composed of a compound semiconductor such as InAs, a metal layer (32B) composed of a metal element such as Ni not composing the compound semiconductor, and an interlayer (33B) of NiInAs or the like composed of the constituent elements of the compound semiconductor and a metal element, the interlayer being situated between the compound semiconductor layer and the metal layer.

For this embodiment, the pin layer (38) is formed under the compound semiconductor layer (31), whereby fixed bias magnetization is applied to the magneto-resistive effect element.

While not shown here, another metal layer, for example, a layer of a precious metal such as Au to inhibit oxidation of the metal layer such as Ni, may be formed on the metal layer such as Ni for this embodiment, similar to the first embodiment.

In the magneto-resistive effect element (30) of the invention, application of a magnetic field (50), particularly a magnetic field applied in the in-plane direction of the interlayer (33B), alters the conductance with respect to the electric current (60) flowing through the metal layer (32B), interlayer (33B) and compound semiconductor layer (31). Specifically, the conductance can be evaluated, for example, by measuring the magnitude of the electric current flowing from a power source (72), using an ammeter (74).

The description of the first embodiment of the magneto-resistive effect element of the present invention applies with regard to the other aspects.

### Fourth Embodiment

As shown in the cross-sectional view of an element in FIG. 4, the fourth embodiment of the magneto-resistive effect element of the present invention has a compound semiconductor layer (41) composed of a compound semiconductor such as InAs, metal layers (42A and 42B) composed of a metal element such as Ni not composing the compound semiconductor, and interlayers (43A and 43B) of NiInAs or the like composed of the constituent elements of the compound semiconductor and a metal element, the interlayers being situated between the compound semiconductor layer and the metal layer.

For this embodiment, the pin layer (48) is formed under the compound semiconductor layer (41), whereby fixed bias magnetization is applied to the magneto-resistive effect element.

While not shown here, another metal layer, for example, a layer of a precious metal such as Au to inhibit oxidation of the metal layer such as Ni, may be formed on the metal layer such as Ni for this embodiment, similar to the first embodiment.

In the magneto-resistive effect element (40) of the invention, application of a magnetic field (50), particularly a magnetic field applied in the in-plane direction of the interlayers (43A and 43B), alters the conductance with respect to the electric current (60) flowing through the metal layer (42B), interlayer (43B), compound semiconductor layer (41), interlayer (43A) and metal layer (42A). Specifically, the conductance can be evaluated, for example, by measuring the magnitude of the electric current flowing from a power source (72), using an ammeter (74).

The description of the first embodiment of the magneto-resistive effect element of the present invention applies with regard to the other aspects.

### EXAMPLES

The present invention is not limited to the examples described above, and may incorporate various modifications based on the gist of the invention which are not excluded from the scope of the invention.

### Example 1

For Example 1, a magneto-resistive effect element having the construction shown in FIG. 1 was fabricated and evaluated.

Specifically, as shown in the cross-sectional view of an element in FIG. 1, the magneto-resistive effect element for Example 1 has a silicon oxide film (16A) with a film thickness of 50 nm on a silicon conductive substrate (16B), and formed over this, a compound semiconductor layer (11) which is an InAs thin-film with a film thickness of 18 nm and planar orientation (100), metal layers (12A and 12B) which are Ni layers each with a film thickness of 15 nm, Au layers (15A and 15B) to inhibit oxidation of the metal layers, and interlayers (13A and 13B) which are NiInAs layers between the compound semiconductor layer (11) and the metal layers (12A and 12B).

That is, the magneto-resistive effect element has a field-effect transistor (FET) structure, wherein the Au layers (15A and 15B), the metal layers (12A and 12B) and the interlayers (13A and 13B) correspond to source and drain electrodes, and the silicon conductive substrate (16B) corresponds to a gate electrode.

The length of the compound semiconductor layer (11) between the interlayers (13A and 13B) of the magneto-resistive effect element, i.e. the length corresponding to the channel length of the TFT, was 10 μm.

For production of the magneto-resistive effect element of Example 1, the compound semiconductor layer (11) as the InAs thin-film was produced according to the method described in Non Patent Documents 3 and 4. Specifically, an InAs thin-film formed on a GaSb substrate by molecular beam epitaxy was transferred onto a silicon oxide film (16A), and then subjected to photolithography, vapor deposition and lift-off to form a Ni layer and Au layer on the InAs thin-film. Before metal vapor deposition, the substrate was dipped for 3 seconds in an aqueous hydrofluoric acid solution with a concentration of 1%, to remove the oxide film that naturally formed on the surface of the InAs thin-film.

The compound semiconductor layer (11) as the InAs thin-film and the metal layers (12A and 12B) as Ni layers, obtained in this manner, were subjected to annealing treatment (heating) in a nitrogen atmosphere, thereby utilizing diffusion to form interlayers (13A and 13B) as NiInAs layers between the compound semiconductor layer (11) and the metal layers (12A and 12B). The annealing treatment was conducted at a temperature of 300° C. for a period of 1 minute.

The magneto-resistive effect element of Example 1 fabricated in this manner was placed in a vacuum, and the conductance property between the Au layers (15A and 15B) with respect to magnetic field change was measured at 9K and at room temperature. The magnetic field orientation was the in-plane direction of the interlayers (13A and 13B).

This produced a distinctly observed magneto-resistive effect both at 9K and at room temperature.

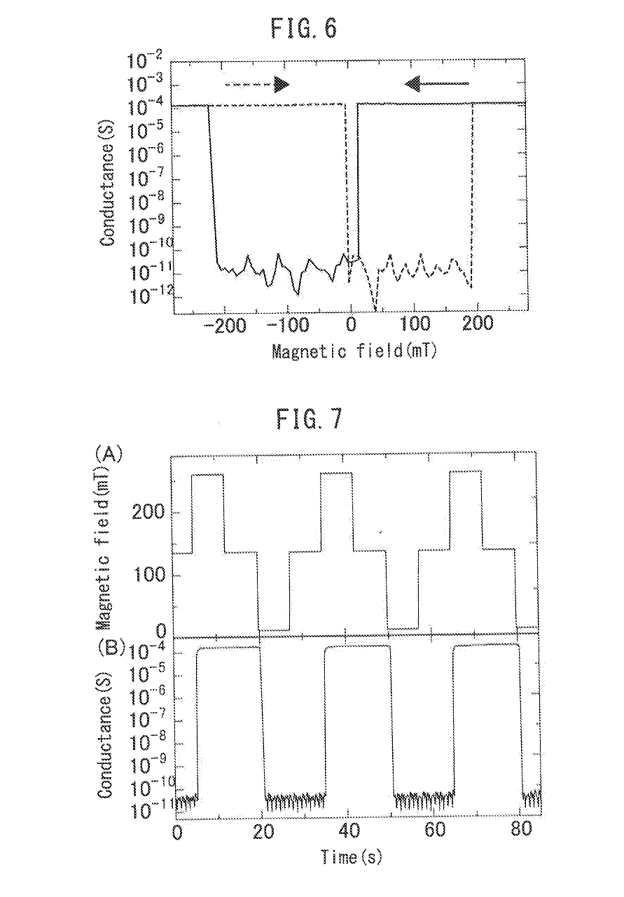

FIG. 6 is a graph showing the magneto-resistive effect obtained at 9K for the magneto-resistive effect element of Example 1. In FIG. 6, the abscissa is the applied magnetic field, and the ordinate is conductance between the Au layers (15A and 15B).

In the magneto-resistive effect element of Example 1, interlayers (13A and 13B) were formed as NiInAs layers between the compound semiconductor layer (11) and the metal layers (12A and 12B). In contrast, with an element without annealing treatment at 300° C., no interlayers (13A and 13B) were formed and no magneto-resistive effect was observed. The interlayers can potentially be Ni fine particles mixed with InAs, a NiAs layer with Ni occupying the In sites, or an alloy of Ni and InAs. When the interlayer is a mixture of Ni fine particles and InAs, the possibility exists of obtaining a magneto-resistive effect between the Ni fine particles that exhibit super-paramagnetism, and the Ni electrodes.

In FIG. 6, the electric current ratio between a low resistance state and a high resistance state is 107, and considering that this is about 1000% (101) even with respect to a large ON/OFF ratio with an ordinary magneto-resistive effect, it is evident that the magneto-resistive effect of the example is extremely large.

FIG. 7 is a graph showing a magneto-resistive effect element of the present invention operated at 9K as a magnetic memory, using the magneto-resistive effect obtained in FIG. 6. In this graph, (A) represents the applied magnetic field, and (B) represents conductance. Regarding the applied magnetic field, the reading magnetic field, writing magnetic field and erasing magnetic field were 140 mT, 260 mT and 10 mT, respectively.

In FIG. 7 as well, an ON/OFF ratio of 10⁷ was obtained.

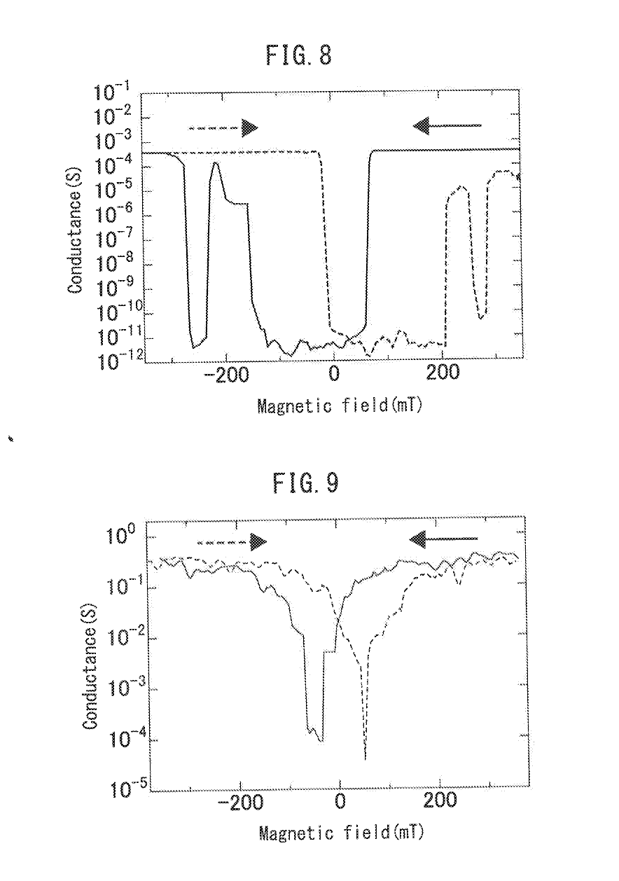

FIG. 8 is graph showing the measurement results for the magneto-resistive effect observed at room temperature, using a magneto-resistive effect element of the present invention. In FIG. 8, the abscissa is the applied magnetic field, and the ordinate is conductance between the Au layers (15A and 15B).

### Example 2

Next, a sulfur-doped InAs substrate with in-plane orientation (100) was used to fabricate the magneto-resistive effect element shown in FIG. 2. The fabricated element was placed in a vacuum, and the conductance property was measured with respect to a magnetic field between two Ni electrodes at 240K. The magnetic field orientation was the in-plane direction of the InAs substrate. As a result, a distinct magneto-resistive effect was observed at 240K, as shown in FIG. 9. In this graph, the abscissa is the applied magnetic field, and the ordinate is conductance between the two Ni electrodes.

Although electric current between two Ni electrodes was measured with this element structure, it is believed that the magneto-resistive effect can be sufficiently obtained if one Ni/InAs interface layer is present.

### INDUSTRIAL APPLICABILITY

The magneto-resistive effect element of the present invention is expected to be applicable to magneto-resistive memories, wherein research is currently advancing toward implementation, and it is expected to play an important role in the field of future spintronics.

### EXPLANATION OF SYMBOLS

10 First embodiment of magneto-resistive effect element of the present invention
11, 21, 31, 41 Compound semiconductor layers
12A, 12B, 22A, 22B, 32B, 42A, 42B Metal layers
13A, 13B, 23A, 23B, 33B, 43A, 43B Interlayers
16A Insulating coating
16B Conductive substrate
15A, 15B Optional additional metal layers
20 Second embodiment of magneto-resistive effect element of the present invention
30 Third embodiment of magneto-resistive effect element of the present invention
38 Pin layer
40 Fourth embodiment of magneto-resistive effect element of the present invention
50 Magnetic field
60 Electric Current
72 Power source
74 Ammeter
C1 State of increased conductance
C2 State of decreased conductance
S1 First threshold magnetic field
S2 Second threshold magnetic field

1. A magneto-resistive effect element, comprising:
a compound semiconductor layer composed of a compound semiconductor,
a metal layer composed of a metal element not composing the compound semiconductor, and
an interlayer between the compound semiconductor layer and the metal layer, composed of the constituent elements of the compound semiconductor and the metal element,
wherein application of a magnetic field alters the conductance with respect to electric current flowing from the compound semiconductor layer side through the interlayer to the metal layer side, and/or electric current flowing in the opposite direction.

2. A magneto-resistive effect element according to claim 1, wherein the magnetic field is a magnetic field applied in the in-plane direction of the interlayer.

3. A magneto-resistive effect element according to claim 1, wherein the conductance is altered by a factor of at least 10³ upon application of the magnetic field.

4. A magneto-resistive effect element according to claim 3, wherein the conductance is altered by a factor of at least 10³ in a 50 mT magnetic field range, upon application of the magnetic field.

5. A magneto-resistive effect element according to claim 1,
wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, and
wherein the first threshold magnetic field is larger than the second threshold magnetic field.

6. A magneto-resistive effect element according to claim 5, wherein the first threshold magnetic field is at least 30 mT larger than the second threshold magnetic field.

7. A magneto-resistive effect element according to claim 5, wherein the second threshold magnetic field is a magnetic field in the same direction as the first threshold magnetic field, and the absolute value of the first threshold magnetic field is larger than the absolute value of the second threshold magnetic field.

8. A magneto-resistive effect element according to claim 1, wherein the compound semiconductor contains In.

9. A magneto-resistive effect element according to claim 8, wherein the compound semiconductor contains As.

10. A magneto-resistive effect element according to claim 8, wherein the compound semiconductor contains Sb.

11. A magneto-resistive effect element according to claim 1, wherein the metal element is Ni.

12. A magneto-resistive memory having a magneto-resistive effect element of claim 1.

13. A method of driving a magneto-resistive memory of claim 12,
wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, the first threshold magnetic field being larger than the second threshold magnetic field, and
wherein the method of driving a magneto-resistive memory comprises the following steps:
(a) applying a magnetic field equal to or larger than the first threshold magnetic field to the interlayer to increase the conductance, thereby writing a state of increased conductance onto the magneto-resistive effect element,
(b) applying a magnetic field smaller than the second threshold magnetic field to the interlayer to decrease the conductance, thereby writing a state of decreased conductance onto the magneto-resistive effect element, and
(c) following the step (a) or (b), evaluating the conductance while applying to the interlayer a magnetic field that is smaller than the first threshold magnetic field and equal to or larger than the second threshold magnetic field, to judge whether the state is one of increased or decreased conductance.

14. A magneto-resistive switch having a magneto-resistive effect element of claim 1.

15. A method of driving a magneto-resistive switch of claim 14,
wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, the first threshold magnetic field being larger than the second threshold magnetic field, and
wherein the method of driving a magneto-resistive switch comprises the following steps:
(a) applying a magnetic field equal to or larger than the first threshold magnetic field to the interlayer to create a state of increased conductance, thereby producing an ON state for electric current flowing from the compound semiconductor layer side through the interlayer toward the metal layer side, and/or in the opposite direction, and
(b) applying a magnetic field smaller than the second threshold magnetic field to the interlayer to create a state of decreased conductance, thereby producing an OFF state for electric current flowing from the compound semiconductor layer side through the interlayer toward the metal layer side, and/or in the opposite direction.

16. A method for producing a magneto-resistive effect element of claim 1, the method comprising:
providing a stack of a compound semiconductor layer composed of a compound semiconductor and a metal layer composed of a metal element not composing the compound semiconductor, and
subjecting the stack to annealing treatment to form an interlayer between the compound semiconductor layer and the metal layer, composed of the constituent elements of the compound semiconductor and the metal element.

17. The method according to claim 16, wherein the annealing treatment is conducted in a temperature range of between 150° C. and 600° C.

18. A magneto-resistive effect element with conductance that varies depending on the magnetic field applied,
wherein the magneto-resistive effect element has a first threshold magnetic field at which the conductance increases as the strength of the magnetic field is increased, and a second threshold magnetic field at which the conductance decreases as the strength of the magnetic field is decreased from a larger magnetic field than the first threshold magnetic field, and
wherein the first threshold magnetic field is larger than the second threshold magnetic field.

19. A magneto-resistive effect element according to claim 18, wherein the first threshold magnetic field is at least 30 mT larger than the second threshold magnetic field.

20. A magneto-resistive effect element according to claim 18, wherein the conductance is altered by a factor of at least 10³ upon application of the magnetic field.

21. A magneto-resistive effect element according to claim 18, wherein the second threshold magnetic field is a magnetic field in the same direction as the first threshold magnetic field, and the absolute value of the first threshold magnetic field is larger than the absolute value of the second threshold magnetic field.

22. A method of driving a magneto-resistive memory having a magneto-resistive effect element of claim 18, which comprises the following steps:
(a) applying a magnetic field equal to or larger than the first threshold magnetic field to the interlayer to increase the conductance, thereby writing a state of increased conductance onto the magneto-resistive effect element,
(b) applying a magnetic field smaller than the second threshold magnetic field to the interlayer to decrease the conductance, thereby writing a state of decreased conductance onto the magneto-resistive effect element, and
(c) following the step (a) or (b), evaluating the conductance while applying to the interlayer a magnetic field that is smaller than the first threshold magnetic field and equal to or larger than the second threshold magnetic field, to judge whether the state is one of increased or decreased conductance.

23. A method of driving a magneto-resistive switch having a magneto-resistive effect element of claim 18, comprising the following steps:
(a) applying a magnetic field equal to or larger than the first threshold magnetic field to the interlayer to create a state of increased conductance, thereby producing an ON state for electric current flowing from the compound semiconductor layer side through the interlayer toward the metal layer side, and/or in the opposite direction, and
(b) applying a magnetic field smaller than the second threshold magnetic field to the interlayer to create a state of decreased conductance, thereby producing an OFF state for electric current flowing from the compound semiconductor layer side through the interlayer toward the metal layer side and/or in the opposite direction.
